(19) United States
(12) Patent Application Publication
(10) Pub. No.: US 2007/0221329 A1
(43) Pub. Date: Sep. 27, 2007

(54) Apparatus and method for distributing a liquid onto a surface of an item

(75) Inventors: Kazuo Sakuma, Tokyo (JP); Inetaro Kurosawa, Tokyo (JP); Kiyoshi Hyodo, Tokyo (JP)

Correspondence Address: TESSERA;LERNER DAVID et al., 600 SOUTH AVENUE WEST, WESTFIELD, NJ, 07090, US

(73) Assignee: Tessera Interconnect Materials, Inc., San Jose, CA (US)

(21) Appl. No.: 11/585,287

(22) Filed: Oct. 23, 2006

Related U.S. Application Data
(63) Continuation of application No. 11/363,401, filed on Feb. 27, 2006, now abandoned.

(30) Foreign Application Priority Data
Mar. 1, 2005 (JP) 2005-56121

(51) Int. Cl. H01L 21/306; B44C 1/22

(52) U.S. Cl. 156/345.11; 216/83; 216/90; 216/91; 156/345.17; 156/345.21

(57) ABSTRACT

An apparatus and method are provided for processing an item by distributing a liquid onto a surface of the item. The apparatus includes a conveyor which defines an undulating path which varies in vertical position relative to the direction of movement of the item conveyable along the path. Thus, the path has at least one apex at a location of the path higher than other locations in the direction of movement along the path. A sprayer is operable to spray the liquid onto the surface of the item at a location that is substantially aligned to the apex of the path.

### CROSS-REFERENCE TO RELATED APPLICATIONS

The present application is a continuation of U.S. patent application Ser. No. 11/363,401, filed Feb. 27, 2006, which is based upon and claims the benefit of priority from Japanese Patent Application No. 2005-056121, filed Mar. 1, 2005, the entire contents of which is incorporated herein by reference.

### BACKGROUND OF THE INVENTION

The present invention relates to apparatuses and methods for distributing a liquid onto a surface of an item. Specific embodiments of the invention relate to apparatuses and methods for controlling a chemical reaction at a surface of an item (such as during an etching process) by spraying a liquid containing a reagent, e.g., an etchant onto a material being processed.

As used herein, the term “wiring board” includes a structure having a dielectric element and a set of wiring patterns therein or thereon, as exposed at one or more major or “primary” external surfaces thereof. Alternatively, or in addition thereto, wiring patterns may be disposed internally within the dielectric element. Wiring boards come in different forms, which include, without limitation, a board, card, substrate, flexible tape, ceramic module and the like. A process is known for manufacturing wiring boards in which a dry film resist layer is photolithographically patterned to expose certain portions of metal layers of a flexible wiring board such as one including a flexible tape. The flexible tape may be such as one including a sheet of polymeric material, for example, polyimide. When the metal layers exposed through the patterned resist film are etched, portions of the metal layers which remain become the wiring patterns.

For good productivity, it is evident that the opposing surfaces of the wiring board should be processed simultaneously. The wiring patterns at both opposing surfaces of the dielectric element can be formed simultaneously by etching the metal layers, using patterned resist films on both opposing surfaces as masks. For example, Japanese Published Unexamined Patent Application Publication No. 2003-276596 describes equipment used to simultaneously etch the opposing surfaces of a wiring board.

FIG. 2 provides a side elevational view of conventional chemical solution processing equipment. As shown therein, a plurality of rollers b are disposed at locations along an essentially linear and horizontal transport path. Direction f indicates the direction that substrates travel along the transport path. A plurality of sprayers c spray an etching solution d onto top and bottom surfaces of the substrate a being processed. In addition, segments e of the linear transport path are provided without rollers b to permit the sprayed etching solution d from the sprayers c to reach the substrate a.

However, there are problems with the processing apparatus shown in FIG. 2. First, the etch rates at the top and bottom surfaces of the substrate a are different. In particular, the etch rate at the top surface tends to be slow. Specifically, the etch rate at the top surface of the substrate a tends to be slower than the etch rate at the bottom surface. In addition, the etch rates on any one of the top or bottom surfaces can differ between the center and the edges of the substrate. In particular, the etch rate at the center of the top surface of the substrate tends to be slow and the etch rate at the edges tends to be faster. These differences in etch rate are problematic because they cause the depth of etching to vary from one location of the substrate to another.

The differences in the etch rates appear to be caused by accumulation of the etching solution at particular locations of the substrate. In order for etching to proceed uniformly, fresh etching solution d must be supplied constantly to the top surface of the substrate a by spraying. In addition, used etching solution needs to be removed rapidly.

However, in the prior art apparatus illustrated in FIG. 2, the etching solution is not removed quickly from the top surface of the substrate. Rather, the etching solution d tends to travel slowly from the center of the substrate towards the edges. Used etching solution d is only removed when it is shed off the edges of the substrate. Because the etching solution sprayed onto the edges of the substrate is shed relatively quickly from the substrate a, the time that the etching solution remains at the edges of the substrate is short. This explains why the etch rate is faster at the edges than at the center of the substrate.

By contrast, in the case of the bottom surface, the etching solution d is sprayed upwards onto the bottom surface of the substrate a. There, the etching solution f drips off the bottom surface under its own weight such that it leaves the bottom surface relatively quickly. Consequently, fresh etching solution is supplied more quickly to the bottom surface than it is to the top surface, causing the etch rate for the bottom surface to be faster than that of the top surface.

A further source of non-uniformity arises due to interference between the etching solution that is supplied by adjacent sprayers c to the major surfaces of the substrate a. Specifically, a portion of the etching solution d supplied by one of the sprayers c can travel along a surface of the substrate towards the adjacent sprayer and mingle with the portion of etching solution freshly supplied by the adjacent sprayer. The fresh etching solution supplied by the adjacent sprayer becomes mixed with the more used etching solution that travels there from nearby. This phenomenon, referred to as “interference,” makes the etching solution less effective at that location, and causes the depth of etching to vary.

Japanese Unexamined Patent Application Publication No. 2001-68826 describes an approach to remedying the above problems. That application describes a multilayer substrate having copper cladding in which the substrate is bent into a convex shape such that left and right sides of the substrate are lower than a higher ridge in the middle of the substrate. Etching solution is provided to both left and right portions of the substrate's surface while the substrate is moved along the processing path. The convex shape of the substrate makes the etch solution less prone to accumulating in puddles at the top or apex of the substrate. However, frequently, an imbalance exists in the amount of etching solution supplied to the left and right portions the surface. Therefore, Japanese Unexamined Patent Application Publication No. 2001-68826 fails to adequately address the problems of non-uniform etch rates.

### SUMMARY OF THE INVENTION

Accordingly, in an embodiment of the invention, an apparatus is provided for processing an item by distributing a liquid onto a surface of the item. The apparatus includes a conveyor which defines an undulating path which varies in vertical position relative to the direction of movement of the item conveyable along the path. Thus, the path has at least one apex at a location of the path higher than other locations in the direction of movement along the path. A sprayer, i.e., a first sprayer, is operable to spray the liquid onto the surface of the item at a location that is substantially aligned to the apex of the path.

According to a preferred aspect of the invention, the conveyor includes a plurality of rollers which support the item, the rollers being disposed at different locations along a direction of movement through the conveyor.

The apparatus can include a second sprayer and the path may further include at least one trough at a location of the path that is lower than other locations in the direction of movement along the path. In such case, the first sprayer is operable to spray the liquid onto a top surface of the item and the second sprayer is operable to spray the liquid onto a bottom surface of the item at a location substantially aligned to the trough.

In a particular embodiment, the conveyor includes a plurality of rollers, i.e., first rollers, for supporting the item. The rollers are disposed at different locations along a direction of movement along the conveyer and define a path supporting the item from below the item. The apparatus further includes second rollers overlying the first rollers. The first and second rollers simultaneously contact the bottom and top surfaces of the item, respectively, and control movement of the item along the path of the conveyor.

Preferably, the liquid which the apparatus is operable to spray includes an etchant for etching a material exposed at the surface of the item contacted by the liquid. For example, the liquid may include an etchant for etching a material exposed at the top and bottom surfaces of the item contacted by the liquid. In such case, the material exposed at the top and bottom surfaces is simultaneously etched using the sprayed liquid.

The apparatus may further include a plurality of axles disposed at different locations in the direction of movement along the path. In such case, each of at least some of the plurality of axles carries a plurality of the rollers.

In accordance with another embodiment of the invention, a method is provided for processing an item by distributing a liquid onto a surface of the item. Such method includes moving the item along a conveyor having an undulating path which varies in vertical position relative to the direction of movement of the item conveyable along the path. The path is such that it has at least one apex at a location of the path higher than other locations in the direction of movement along the path and the liquid is sprayed onto a top surface of the item at a location substantially aligned to the apex of the path.

Preferably, the path further includes at least one trough at a location of the path lower than other locations in the direction of movement along the path. Preferably, the method further includes spraying the liquid onto a bottom surface of the item at a location substantially aligned to the trough of the path.

In a preferred embodiment, the liquid includes an etchant for etching a material exposed at the top surface of the item and the method further includes etching the exposed material using the sprayed liquid. For example, the liquid may include an etchant for etching a material exposed at the top and bottom surfaces of the item, and the method may further include simultaneously etching the material exposed at the top and bottom surfaces using the sprayed liquid.

### BRIEF DESCRIPTION OF THE DRAWINGS

FIG. 1(A) is a side elevational view of apparatus in accordance with an embodiment of the invention for processing an item by distributing a liquid onto the item's surface.

FIG. 1(B) is a plan view of a conveyor mechanism such as included in the apparatus of FIG. 1(A) in accordance with one embodiment of the invention.

FIG. 2 is a side elevational view of a chemical solution processing apparatus in accordance with the prior art.

### DETAILED DESCRIPTION

Accordingly, embodiments of the invention described herein address problems including etch rate nonuniformity as described above in the background.

In accordance with embodiments of the invention described below, imbalances in the etch rate between the top and bottom surfaces are addressed without causing imbalance in the etch rate between left and right portions of the top surface or of the bottom surface. In addition, embodiments of the invention described herein address the aforementioned problem of interference between portions of the liquid, e.g., an etching liquid, that are supplied by different sprayers.

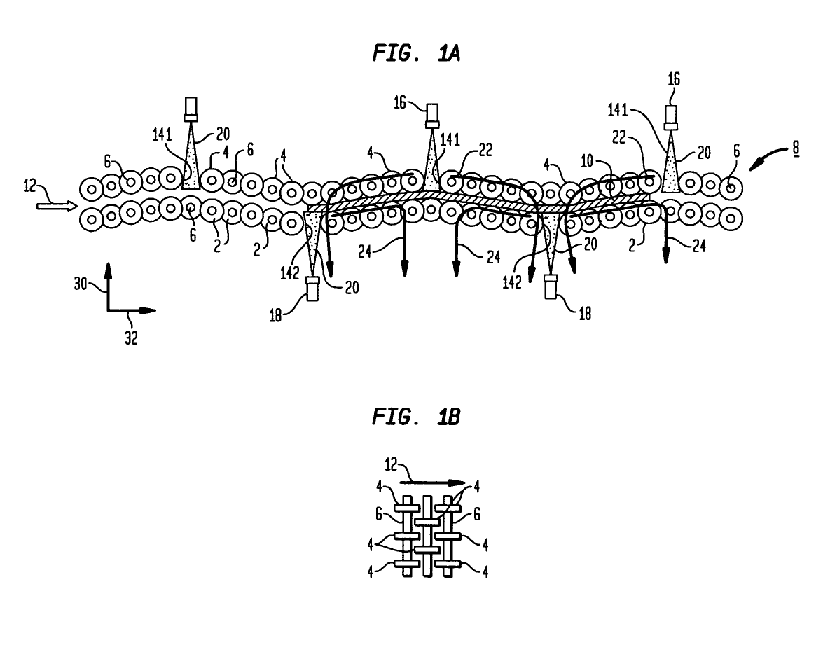

As depicted in the side elevational view of FIG. 1, an apparatus for distributing a liquid onto a surface of an item in accordance with an embodiment of the invention includes a conveyor mechanism 8 or “conveyor” having an undulating shape in form of a wave. Conveyor 8 includes a plurality of top rollers 4 and a plurality of bottom rollers 2. Axles 6 support the rollers 2, 4 and position the rollers in relation to the direction 12 in which the substrate 10 travels along the conveyor 8. The positions of individual axles 6 in a vertical direction 30 vary in relation to their positions along the horizontal direction 32 of movement 12 of the conveyor. In such manner, the conveyor 8 has an undulating or wave-like shape. Preferably, one of each adjacent pair of axles 6 carrying rollers 2 is higher than the other and one of each adjacent pair of axles 6 carrying rollers 4 is higher than the other.

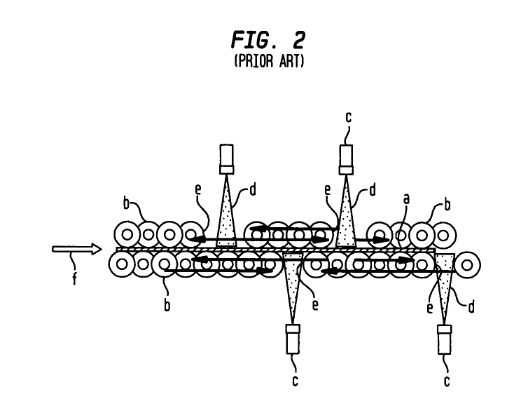

In addition, as seen in the plan view of FIG. 2(B), there are rollers 4 of axles which are adjacent to each other in the direction 12 of the conveyor's movement. These adjacent rollers are offset from each other in the axial direction along each axle. This arrangement helps to assure that the rollers 4 of adjacent axles contact the substrate at locations that are relatively close to each other in the direction 12 of the conveyor's movement.

In certain locations 141 of the conveyor 8 no rollers are present, such that a liquid, for example, an etchant or etching solution 20 can be sprayed by sprayers 16 onto exposed portions of the top surface and the bottom surface of the substrate 10 opposite the top surface. As depicted in FIG. 1, the movement of the substrate 10 along the conveyor 8 traces out a wave-shaped path. In addition, sprayers 16 are positioned so as to apply the liquid, e.g., etching solution 20 to the substrate 10 at apexes of the undulating path of the conveyor 8. This arrangement causes the liquid to flow relatively quickly away from portions of the surface of the substrate at those apexes. Thus, the liquid is shed from the top surface of the substrate, as shown by arrow 22. Consequently, with the liquid quickly leaving the initial area 141 of application and shedding from the substrate, fresh liquid can be supplied more quickly to the same portions of the top surface.

In a particular embodiment, when the liquid contains an etchant or etching solution, etching is performed using the liquid distributed onto the surface or the top and bottom surfaces. In such case, fresh etchant is supplied more quickly to the top surface, thus making the rate of etching the top surface more uniform across the top surface and more uniform with respect to the rate of etching the bottom surface. In addition, because the etching solution flows quickly downwardly away from each of the areas 141 where it is applied to the substrate 10, the portions of etching solution supplied by adjacent sprayers 16 are less likely to become mixed. Thus, the spraying of the etching solution 141 at the apexes of the substrate 10 significantly reduces the aforementioned problem of interference.

With the etch rate of the top surface of the substrate increased and made more uniform, the etch rate of the top surface is made more uniform with respect to that of the bottom surface of the substrate.

In addition, because the substrate being processed does not need to be bent between left and right edges, as viewed in the direction of travel along the conveyor, it is not likely to exhibit different etch rates between the left and right portions of the substrate. Consequently, there is less need to vary the pressure of the spray exiting particular sprayers to adjust for such etch rate variations, i.e., for such imbalance.

As also seen from FIG. 1, further sprayers 18 are positioned to spray at locations 142 onto the bottom surface of the substrate 10. However, the spray dispensed by sprayers 18 strikes the bottom surface at low locations (troughs) within the undulating path of the conveyor 8. During movement of the substrate along the path, movement of the sprayed on liquid from one trough location towards the next trough location of the adjacent sprayer is impeded due to the upward slope of the path between the two sprayers 18. Arrows 24 indicate the path that etching solution travels during movement of the substrate along the conveyor. As apparent by viewing FIG. 1, the dispensed liquid sheds or leaves the bottom surface of the substrate 10 under its own weight prior to causing interference with the freshly supplied liquid provided by the adjacent sprayer 18.

Again, when the liquid contains an etchant or etching solution, etching is performed using the liquid distributed onto the surface or the top and bottom surfaces. In such case, fresh etchant is supplied more quickly to portions of the bottom surface than before, making the rate of etching the bottom surface more uniform across the bottom surface. In addition, because the etching solution sheds quickly away from each of the areas 142 where it is applied to the bottom surface of the substrate 10, the portions of etching solution supplied by adjacent sprayers 18 are less likely to become mixed. Thus, the spraying of the etching solution onto areas 142 of the substrate 10 at the troughs significantly reduces the aforementioned problem of interference.

Accordingly, it is seen that the aforementioned problems of spatially nonuniform etch rates and interference are addressed by the embodiments of the invention described herein.

Embodiments of the invention are applicable to processing in which a liquid is supplied to a surface of an item to be processed, for example by etching or other processing using distribution of a liquid, especially a liquid which reacts with a material present at an exposed surface of the item. More particularly, embodiments of the invention find application in the simultaneous processing, e.g., etching of metal layers, exposed at respective opposite surfaces of a substrate, for example in the manufacture of a wiring circuit board. In addition, embodiments of the invention can be further applied to the etching of a metal layer selectively to an underlying etch stop layer or etching barrier layer, such as, for example, in the fabrication of conductive bumps projecting above the underlying substrate. In addition, the principles of the embodiments described herein can be applied to the fabrication of an interconnection circuit board fabrication member having a three-layer structure including metal wiring patterns that are formed by etching selectively to a material of an underlying etching barrier layer.

1. An apparatus for processing an item by distributing a liquid onto a surface of the item, comprising:
a conveyor defining an undulating path which varies in vertical position relative to the direction of movement of the item conveyable along the path, the path having at least one apex at a location of the path higher than other locations in the direction of movement along the path; and
a first sprayer operable to spray the liquid onto the surface of the item, the sprayer being operable to spray the surface of the item at a location substantially aligned to the apex of the path.

2. The apparatus as claimed in claim 1, wherein the conveyor includes a plurality of rollers for supporting the item, the plurality of rollers being disposed at different locations along a direction of movement through the conveyor.

3. The apparatus as claimed in claim 1, further comprising a second sprayer, wherein the path further includes at least one trough at a location of the path lower than other locations in the direction of movement along the path, the first sprayer being operable to spray the liquid onto a top surface of the item and the second sprayer being operable to spray the liquid onto a bottom surface of the item at a location substantially aligned to the trough.

4. The apparatus as claimed in claim 2, wherein the conveyor includes a plurality of rollers for supporting the item, the plurality of rollers being disposed at different locations along a direction of movement through the conveyor, the rollers of the conveyor being first rollers, the path defined by the first rollers supporting the item from below the item, the apparatus further comprising second rollers overlying the first rollers, the first and second rollers simultaneously contacting the bottom and top surfaces of the item, respectively, for controlling movement of the item along the path of the conveyor.

5. The apparatus as claimed in claim 1, wherein the liquid includes an etchant for etching a material exposed at the surface of the item contacted by the liquid.

6. The apparatus as claimed in claim 2, wherein the liquid includes an etchant for etching a material exposed at the top and bottom surfaces of the item contacted by the liquid, such that the material exposed at the top and bottom surfaces is simultaneously etched using the sprayed liquid.

7. The apparatus as claimed in claim 2, further comprising a plurality of axles disposed at different locations in the direction of movement along the path, wherein each of at least some of the plurality of axles carries a plurality of the rollers.

8. A method for processing an item by distributing a liquid onto a surface of the item, comprising:
moving the item along a conveyor having an undulating path which varies in vertical position relative to the direction of movement of the item conveyable along the path, the path having at least one apex at a location of the path higher than other locations in the direction of movement along the path; and
spraying the liquid onto a top surface of the item at a location substantially aligned to the apex of the path.

9. The method as claimed in claim 8, wherein the path further includes at least one trough at a location of the path lower than other locations in the direction of movement along the path, the method further comprising spraying the liquid onto a bottom surface of the item at a location substantially aligned to the trough of the path.

10. The method as claimed in claim 8, wherein the liquid includes an etchant for etching a material exposed at the top surface of the item, the method further comprising etching the exposed material using the sprayed liquid.

11. The method as claimed in claim 9, wherein the liquid includes an etchant for etching a material exposed at the top and bottom surfaces of the item, the method further comprising simultaneously etching the material exposed at the top and bottom surfaces using the sprayed liquid.
